(19) United States
(12) Patent Application Publication
(10) Pub. No.: US 2026/0047078 A1
(43) Pub. Date: Feb. 12, 2026

(54) SEMICONDUCTOR DEVICE INCLUDING CAPACITOR

(71) Applicant: Samsung Electronics Co., Ltd., Suwon-si (KR)

(72) Inventors: Seongtak CHO, Suwon-si (KR); Jongmin KIM, Suwon-si (KR); Seungmuk KIM, Suwon-si (KR); Yongkwan KIM, Suwon-si (KR); Huijung KIM, Suwon-si (KR); Hongjun LEE, Suwon-si (KR)

(73) Assignee: Samsung Electronics Co., Ltd., Suwon-si (KR)

(21) Appl. No.: 19/276,172

(22) Filed: Jul. 22, 2025

(30) Foreign Application Priority Data
Aug. 8, 2024 (KR) 10-2024-0106336

(51) Int. Cl. H10B 12/00

(52) U.S. Cl. CPC H10B 12/318; H10B 12/315; H10B 12/50; H10B 12/033; H10B 12/09

(57) ABSTRACT

A semiconductor device includes a substrate including a cell array area and a peripheral circuit area, a capacitor structure formed on the cell array area of the substrate, a dam structure surrounding the capacitor structure in a planar view, a peripheral circuit insulating layer disposed on the peripheral circuit area of the substrate and on a sidewall of the dam structure and including a first mold insulating layer, a first supporter layer disposed on the first mold insulating layer, and a second mold insulating layer disposed on the first supporter layer, and a peripheral circuit contact disposed on the peripheral circuit area of the substrate, and extending through the peripheral circuit insulating layer in a first direction perpendicular to an upper surface of the substrate.

### CROSS-REFERENCE TO RELATED APPLICATION

This application is based on and claims priority under 35 U.S. C. § 119 to Korean Patent Application No. 10-2024-0106336, filed on Aug. 8, 2024, in the Korean Intellectual Property Office, the disclosure of which is incorporated by reference herein in its entirety.

### BACKGROUND

The inventive concepts relate to a semiconductor device, and more particularly, to a semiconductor device including a capacitor.

In accordance with the downscaling of semiconductor devices, the sizes of the footprint for individual microcircuit patterns for implementing semiconductor devices are being further reduced. In addition, as integrated circuit (IC) devices become more highly integrated, the height of a capacitor and the height of a peripheral circuit contact are being increased to compensate, which may lead to misalignment defects in a process of forming the peripheral circuit contact.

### SUMMARY

The inventive concepts provide a semiconductor device configured to prevent, or reduce the potential for, a misalignment defect in a process of forming a peripheral circuit contact.

According to an aspect of the inventive concepts, there is provided a semiconductor device including a substrate including a cell array area and a peripheral circuit area, a capacitor structure on the cell array area of the substrate, a dam structure surrounding the capacitor structure in a planar view, a peripheral circuit insulating layer on the peripheral circuit area of the substrate and on a sidewall of the dam structure, the peripheral circuit insulating layer including a first mold insulating layer, a first supporter layer on the first mold insulating layer, and a second mold insulating layer on the first supporter layer such that the first supporter layer is between the first and second mold insulating layers, and a peripheral circuit contact on the peripheral circuit area of the substrate, the peripheral circuit contact extending through the peripheral circuit insulating layer in a vertical direction perpendicular to an upper surface of the substrate.

According to another aspect of the inventive concepts, there is provided a semiconductor device including a substrate including a cell array area and a peripheral circuit area, a capacitor structure on the cell array area of the substrate and including a plurality of lower electrodes extending in a vertical direction perpendicular to an upper surface of the substrate, a first cell supporter pattern on a part of sidewalls of the plurality of lower electrodes, a capacitor dielectric layer on the sidewalls of the plurality of lower electrodes and an upper surface and a bottom surface of the first cell supporter pattern, and an upper electrode on the capacitor dielectric layer and covering the plurality of lower electrodes and the first cell supporter pattern, a peripheral circuit insulating layer on the peripheral circuit area of the substrate and including a first mold insulating layer, a first supporter layer on the first mold insulating layer, the first supporter layer at a same vertical level as the first cell supporter pattern, and a second mold insulating layer on the first supporter layer such that the first supporter layer is between the first and second mold insulating layers, and a peripheral circuit contact on the peripheral circuit area of the substrate, peripheral circuit contact extending in the vertical direction through the peripheral circuit insulating layer.

According to another aspect of the inventive concepts, there is provided a semiconductor device including a substrate including a cell array area and a peripheral circuit area, a capacitor structure formed on the cell array area of the substrate and including a plurality of lower electrodes extending in a vertical direction perpendicular to an upper surface of the substrate, a first cell supporter pattern on a first portion of sidewalls of the plurality of lower electrodes, a second cell supporter pattern on a second portion of the sidewalls of the plurality of lower electrodes such that the second cell supporter pattern is at a higher vertical level than the first cell supporter pattern, a capacitor dielectric layer on the sidewalls of the plurality of lower electrodes, an upper surface and a bottom surface of the first cell supporter pattern, and an upper surface and a bottom surface of the second cell supporter pattern; and an upper electrode on the capacitor dielectric layer and covering the plurality of lower electrodes, the first cell supporter pattern, and the second cell supporter pattern, a peripheral circuit insulating layer on the peripheral circuit area of the substrate and including a first mold insulating layer, a first supporter layer on the first mold insulating layer, the first supporter layer at a same vertical level as the first cell supporter pattern, a second mold insulating layer on the first supporter layer such that the first supporter layer is between the first and second mold insulating layers,, and a second supporter layer on the second mold insulating layer, the second supporter layer at a same vertical level as the second cell supporter pattern, a dam structure between the capacitor structure and the peripheral circuit insulating layer and, in a planar view, surrounding the capacitor structure, a peripheral circuit contact on the peripheral circuit area of the substrate, and extending through the peripheral circuit insulating layer in the vertical direction, an upper insulating layer on an upper surface of the capacitor structure and an upper surface of the peripheral circuit insulating layer, a first upper contact penetrating the upper insulating layer such that the first upper contact is electrically connected to the upper electrode, and a second upper contact penetrating the upper insulating layer such that the second upper contact is electrically connected to the peripheral circuit contact.

### BRIEF DESCRIPTION OF THE DRAWINGS

Embodiments will be more clearly understood from the following detailed description taken in conjunction with the accompanying drawings in which:

FIG. 1 is a layout diagram illustrating a semiconductor device according to some embodiments;

FIG. 2 is a cross-sectional view taken along line A-A′ of FIG. 1;

FIG. 3 is a plan layout diagram of a cell array area and a peripheral circuit area at a first vertical level of FIG. 2;

FIG. 4 is a plan layout diagram of a cell array area and a peripheral circuit area at a second vertical level of FIG. 2;

FIG. 5 is a cross-sectional view illustrating a cell transistor included in a semiconductor device according to some embodiments;

FIG. 6 is a cross-sectional view illustrating a semiconductor device according to some embodiments;

FIG. 7 is a cross-sectional view illustrating a semiconductor device according to some embodiments;

FIG. 8 is a plan layout diagram at a first vertical level of FIG. 7;

FIG. 9 is a plan layout diagram illustrating a semiconductor device according to some embodiments;

FIG. 10 is a cross-sectional view illustrating a semiconductor device according to some embodiments;

FIGS. 11, 12A, 13, 14, 15A, and 16 to 19 are cross-sectional views illustrating a method of manufacturing a semiconductor device according to some embodiments; FIGS. 12B and 15B are plan layout diagrams at the first vertical level of FIGS. 12A and 15A; FIGS. 12C and 15C are plan layout diagrams at the second vertical level of FIGS. 12A and 15A;

FIGS. 20 and 21 are cross-sectional views illustrating a method of manufacturing a semiconductor device according to some embodiments;

FIGS. 22 to 26 are cross-sectional views illustrating a method of manufacturing a semiconductor device according to some embodiments; and

FIGS. 27 and 28 are cross-sectional views illustrating a method of manufacturing a semiconductor device according to some embodiments.

### DETAILED DESCRIPTION OF THE EMBODIMENTS

Hereinafter, embodiments of the inventive concepts will be described in detail with reference to the attached drawings. Throughout the drawings, like reference numerals indicate like elements; thus, redundant descriptions thereof may be omitted for conciseness. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Additionally, spatially relative terms, such as “above”, “lower” “below”, and/or similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly.

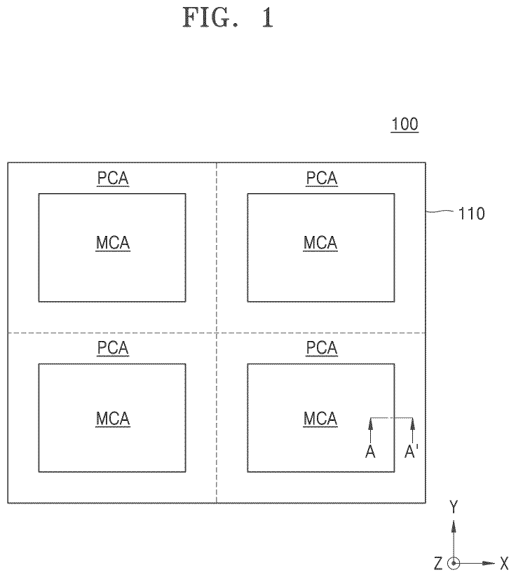

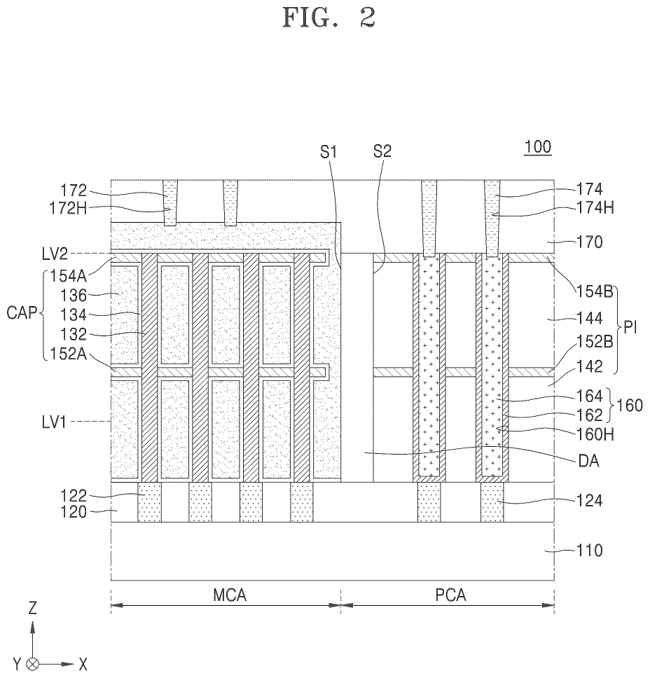

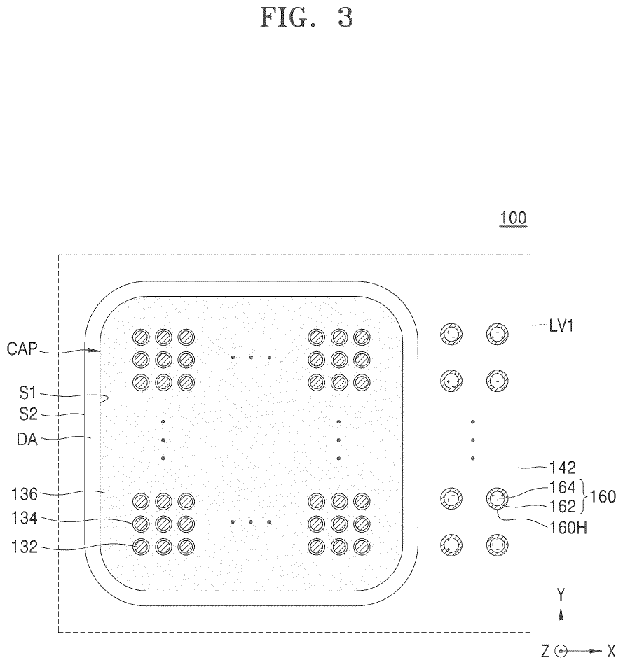

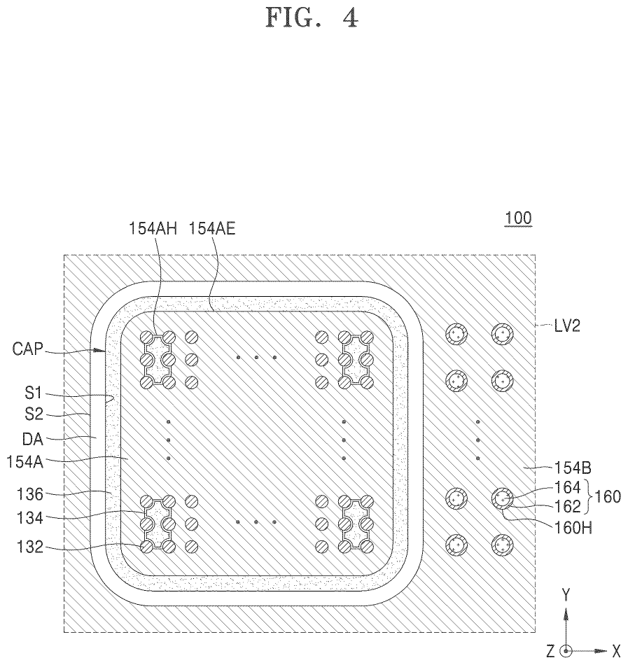

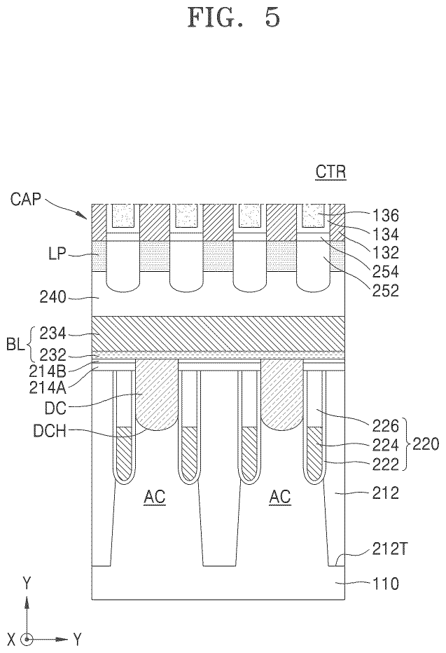

FIG. 1 is a layout diagram illustrating a semiconductor device 100 according to some embodiments. FIG. 2 is a cross-sectional view taken along line A-A′ of FIG. 1. FIG. 3 is a plan layout diagram of a cell array area MCA and a peripheral circuit area PCA at a first vertical level LV1 of FIG. 2. FIG. 4 is a plan layout diagram of the cell array area MCA and the peripheral circuit area PCA at a second vertical level LV2 of FIG. 2. FIG. 5 is a cross-sectional view illustrating a cell transistor CTR included in the semiconductor device 100 according to some embodiments.

Referring to FIGS. 1 to 4, a semiconductor device 100 may include a substrate 110 including the cell array area MCA and the peripheral circuit area PCA. The cell array area MCA may be a memory cell area of a dynamic random access memory (DRAM) device, and the peripheral circuit area PCA may be a core area or a peripheral circuit area of the DRAM device. For example, the cell array area MCA may include the cell transistor CTR and a capacitor structure CAP connected thereto, and the peripheral circuit area PCA may include a peripheral circuit transistor configured to transmit a signal and/or power to a cell transistor CTR included in the cell array area MCA. In some embodiments, the peripheral circuit transistor may further constitute various circuits such as a command decoder, a control logic, an address buffer, a row decoder, a column decoder, a sense amplifier, a data input/output circuit, and/or the like.

A lower structure 120 may be disposed on the substrate 110. A plurality of first conductive patterns 122 through the lower structure 120 may be disposed on the cell array area MCA of the substrate 110, and a plurality of second conductive patterns 124 penetrating the lower structure 120 may be disposed on the peripheral circuit area PCA of the substrate 110.

In some embodiments, the lower structure 120 may include an insulating layer including, e.g., a silicon oxide layer, a silicon nitride layer, and/or a combination thereof. In some embodiments, the lower structure 120 may further include various conductive areas, for example, a wiring layer; a contact plug; a transistor, an insulating layer insulating the wiring layer, the contact plug, and the transistor from each other; and/or the like.

In some embodiments, the plurality of first conductive patterns 122 and the plurality of second conductive patterns 124 may include polysilicon, metal, conductive metal nitride, metal silicide, a combination thereof, and/or the like. For example, in at least some embodiments, the plurality of first conductive patterns 122 and the plurality of second conductive patterns 124 may each include a conductive (e.g., zero-bandgap) material and/or the like.

The capacitor structure CAP may be disposed on the cell array area MCA of the substrate 110. The capacitor structure CAP may include a plurality of lower electrodes 132, a capacitor dielectric layer 134, an upper electrode 136, a first cell supporter pattern 152A, and a second cell supporter pattern 154A.

In some embodiments, the plurality of lower electrodes 132 may respectively extend from the plurality of first conductive patterns 122 in a vertical direction Z. For example, each of the plurality of lower electrodes 132 may have a pillar shape extending in a direction away from the substrate 110 in the vertical direction Z from an upper surface of the first conductive pattern 122. An example in which each of the plurality of lower electrodes 132 has the pillar shape has been described, but the inventive concepts are not limited thereto. For example, in some embodiments, the plurality of lower electrodes 132 may include lower electrodes 132 having a cross-sectional structure of a cup shape or a cylinder shape with a closed bottom portion.

A first cell supporter pattern 152A may be disposed on a first portion of each of sidewalls of the plurality of lower electrodes 132, and a second cell supporter pattern 154A may be disposed on a second portion of each of the sidewalls of the plurality of lower electrodes 132. The first cell supporter pattern 152A may be a flat layer extending in a first horizontal direction X and/or a second horizontal direction Y, and the second cell supporter pattern 154A may be a flat layer extending in the first horizontal direction X and/or the second horizontal direction Y at a higher vertical level than the first cell supporter pattern 152A. The plurality of lower electrodes 132 may extend in the vertical direction Z through the first cell supporter pattern 152A and the second cell supporter pattern 154A.

In some embodiments, the plurality of lower electrodes 132 may each include a conductive material, such as, at least one of Ti, TiN, Ta, TaN, W, WN, TiSiN, WSiN, a combination thereof, and/or the like.

In some embodiments, as shown in FIG. 4, the second cell supporter pattern 154A may include a plurality of openings 154AH, and a part of the sidewalls of the plurality of lower electrodes 132 may be exposed by the plurality of openings 154AH. FIG. 4 shows that each of the plurality of openings 154AH has a rectangular planar shape, but the planar shape of the plurality of openings 154AH is not limited thereto, and the plurality of openings 154AH may have various shapes, such as a circle, an oval, a triangle, a square, a hexagon, a parallelogram, a rhombus, etc.

In some embodiments, the first cell supporter pattern 152A may also include a plurality of openings each having a shape the same as and/or substantially similar to that of the plurality of openings 154AH of the second cell supporter pattern 154A shown in FIG. 4.

In some embodiments, the first cell supporter pattern 152A and the second cell supporter pattern 154A may include silicon nitride, silicon carbide, silicon boron nitride, or a combination thereof. In some embodiments, the second cell supporter pattern 154A may include the same material as the first cell supporter pattern 152A, or may include a different material from the first cell supporter pattern 152A.

In some embodiments, an upper surface of the lower electrode 132 may be disposed on the same plane as an upper surface of the second cell supporter pattern 154A, but the inventive concepts are not limited thereto.

FIG. 2 shows that the first cell supporter pattern 152A and the second cell supporter pattern 154A are spaced apart from each other on the sidewall of the lower electrode 132, but an additional cell supporter pattern (not illustrated) may be further disposed at a vertical level different from the first cell supporter pattern 152A and the second cell supporter pattern 154A, for example, between the first cell supporter pattern 152A and the second cell supporter pattern 154A.

In some embodiments, the capacitor dielectric layer 134 may be conformally disposed on the sidewall of the lower electrode 132 and may extend onto top and bottom surfaces of the first cell supporter pattern 152A and onto top and bottom surfaces of the second cell supporter pattern 154A.

In some embodiments, the capacitor dielectric layer 134 may include a high-k dielectric layer. The high-k dielectric layer refers to a dielectric layer having a dielectric constant higher than that of a silicon oxide layer. In some embodiments, the capacitor dielectric layer 134 may include a metal oxide including at least of hafnium (Hf), zirconium (Zr), aluminum (Al), niobium (Nb), cerium (Ce), lanthanum (La), tantalum (Ta), and/or titanium (Ti).

In some embodiments, the capacitor dielectric layer 134 may include a ferroelectric material layer, an anti-ferroelectric material layer, a paraelectric material layer, or a combination thereof. In some examples, the capacitor dielectric layer 134 may have a stack structure of a first dielectric layer including the ferroelectric material layer and a second dielectric layer including the anti-ferroelectric material layer. In some examples, the capacitor dielectric layer 134 may have a stack structure of a first dielectric layer including the ferroelectric material layer and a second dielectric layer including the paraelectric material layer.

The upper electrode 136 may be disposed on the capacitor dielectric layer 134, and may be disposed to cover the plurality of lower electrodes 132, the first cell supporter pattern 152A, and the second cell supporter pattern 154A. In some embodiments, the upper electrode 136 may be disposed to cover an end portion 154AE of the second cell supporter pattern 154A such that, e.g., a portion of upper electrode 136 extends from the end portion 154AE of the second cell supporter pattern 154A in the first horizontal direction X and/or the second horizontal direction Y.

In some embodiments, the upper electrode 136 may include a conductive material, such as, at least one of Ti, TiN, Ta, TaN, W, WN, TiSiN, WSiN, Si, SiGe, or a combination thereof. The conductive material of the upper electrode 136 and the lower electrodes 132 may be, e.g., the same and/or different.

In some embodiments, a dam structure DA may be disposed at a boundary between the cell array area MCA and the peripheral circuit area PCA (or the dam structure DA may be disposed at an edge portion of the peripheral circuit area PCA adjacent to the cell array area MCA).

In a planar view, the dam structure DA may be disposed to surround the capacitor structure CAP. The dam structure DA may include an inner wall S1 and an outer wall S2, and the capacitor structure CAP may be disposed within a closed curve limited by the inner wall S1 of the dam structure DA in a planar view. For example, the inner wall S1 of the dam structure DA may be in contact with a sidewall of the upper electrode 136 of the capacitor structure CAP and surround the sidewall of the upper electrode 136. In some embodiments, the dam structure DA may have an upper surface disposed at the same level as the upper surface of the second cell supporter pattern 154A, and an upper surface of the capacitor structure CAP, for example, an upper surface of the upper electrode 136, may be disposed at a higher level than the upper surface of the dam structure DA.

In some embodiments, the dam structure DA may include silicon nitride, silicon carbide, silicon boron nitride, a combination thereof, and/or the like.

A peripheral circuit insulating layer PI may be disposed on the peripheral circuit area PCA of the substrate 110. The peripheral circuit insulating layer PI may be disposed on the outer wall S2 of the dam structure DA. In some embodiments, the dam structure DA may be disposed between the peripheral circuit insulating layer PI and the capacitor structure CAP, and the peripheral circuit insulating layer PI may be disposed to surround the dam structure DA in a planar view. In some embodiments, an upper surface of the peripheral circuit insulating layer PI may be disposed at the same level as the upper surface of the dam structure DA.

In some embodiments, the peripheral circuit insulating layer PI may include a first mold insulating layer 142, a first supporter layer 152B, a second mold insulating layer 144, and a second supporter layer 154B which are sequentially formed on the lower structure 120.

In some embodiments, the first mold insulating layer 142 and the second mold insulating layer 144 may each include silicon oxide, silicon nitride, silicon carbide, silicon boron nitride, a combination thereof, and/or the like.

In some embodiments, the first supporter layer 152B may include the same material as a material of the first cell supporter pattern 152A. In some embodiments, the first cell supporter pattern 152A and the first supporter layer 152B may each include silicon nitride. In some embodiments, the first cell supporter pattern 152A and the first supporter layer 152B may each include silicon carbide. In some embodiments, the first cell supporter pattern 152A and the first supporter layer 152B may each include silicon boron nitride. In some embodiments, the first and second supporter layers 152B and 154B may include a different material to the first and second mold insulating layers 142 and 144.

In some embodiments, an upper surface of the first supporter layer 152B may be disposed at the same vertical level as an upper surface of the first cell supporter pattern 152A. In some embodiments, a thickness of the first supporter layer 152B in the vertical direction Z may be the same as a thickness of the first cell supporter pattern 152A in the vertical direction Z. In some embodiments, the first supporter layer 152B and the first cell supporter pattern 152A may be formed using the same manufacturing process. In some embodiments, the first supporter layer 152B may be disposed to cover the entire upper surface of the first mold insulating layer 142.

In some embodiments, an upper surface of the second supporter layer 154B may be disposed at the same vertical level as an upper surface of the second cell supporter pattern 154A. In some embodiments, a thickness of the second supporter layer 154B in the vertical direction Z may be the same as a thickness of the second cell supporter pattern 154A in the vertical direction Z. In some embodiments, the second supporter layer 154B and the second cell supporter pattern 154A may be formed using the same manufacturing process. In some embodiments, the second supporter layer 154B may be disposed to cover the entire upper surface of the second mold insulating layer 144.

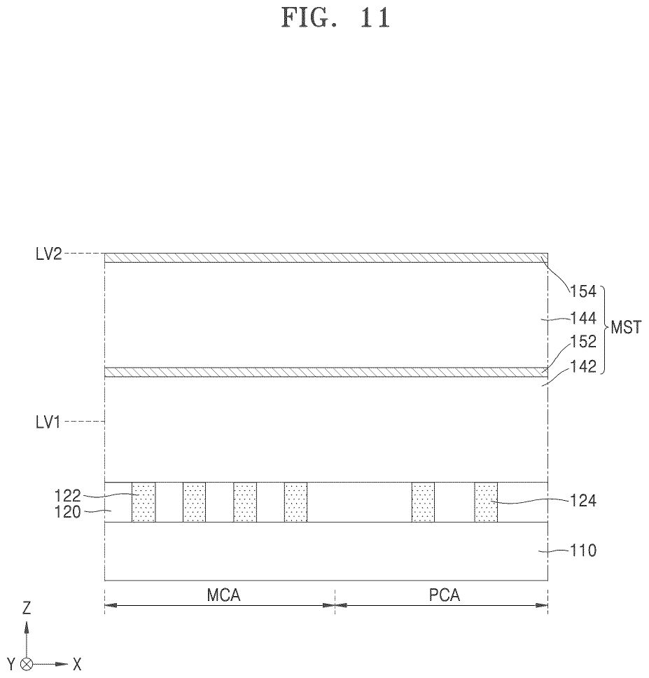

In some embodiments, the peripheral circuit insulating layer PI may be a part of a mold stack MST (see FIG. 11) used as a mold structure to form the lower electrode 132 in the cell array area MCA. In some embodiments, while the first mold insulating layer 142L and the second mold insulating layer 144L of the mold stack MST disposed in the cell array area MCA are removed, the first mold insulating layer 142L and the second mold insulating layer 144L of the mold stack MST disposed in the peripheral circuit area PCA may be covered by the dam structure DA and remain.

A peripheral circuit contact 160 extending through the peripheral circuit insulating layer PI and in the vertical direction Z may be disposed on the peripheral circuit area PCA of the substrate 110. The peripheral circuit contact 160 may be disposed in a peripheral circuit contact hole 160H through the peripheral circuit insulating layer PI. The peripheral circuit contact 160 may extend in the vertical direction Z through the first mold insulating layer 142, the first supporter layer 152B, the second mold insulating layer 144, and the second supporter layer 154B.

The peripheral circuit contact 160 may include a conductive barrier layer 162 disposed on an inner wall of the peripheral circuit contact hole 160H and a contact plug 164 filling the inside of the peripheral circuit contact hole 160H. In some embodiments, the conductive barrier layer 162 may include at least one of Ti, TiN, Ta, TaN, W, WN, TiSiN, or WSiN. In some embodiments, the contact plug 164 may include at least one of Ti, TiN, Ta, TaN, W, WN, TiSiN, or WSiN. In some embodiments, the conductive barrier layer 162 and the contact plug 164 may include the same and/or different materials.

In some embodiments, the conductive barrier layer 162 and/or the contact plug 164 may be formed in a process of forming the lower electrode 132.

An upper insulating layer 170 may be disposed on an upper surface of each of the capacitor structure CAP, the dam structure DA, and the peripheral circuit insulating layer PI.

A first upper contact 172 may be disposed in a first contact hole 172H through the upper insulating layer 170. The first upper contact 172 may be disposed on the upper surface of the upper electrode 136 and may be electrically connected to the upper electrode 136.

A second upper contact 174 may be disposed in a second contact hole 174H through the upper insulating layer 170. The second upper contact 174 may be disposed on the upper surface of the peripheral circuit contact 160 and may be electrically connected to the peripheral circuit contact 160. The first and second upper contacts 172 and 174 may each include a conductive material.

FIG. 5 is the cross-sectional view of the cell transistor CTR according to some embodiments. As shown in FIG. 5, a device isolation trench 212T may be formed in the substrate 110, and a device isolation layer 212 may be formed in the device isolation trench 212T. A plurality of active areas AC may be defined in the cell array area MCA of the substrate 110 by the device isolation layer 212.

The substrate 110 may include, a semiconductor, such as silicon, for example, single crystal silicon, polycrystalline silicon, or amorphous silicon. In some embodiments, the substrate 110 may include at least one selected from Si, Ge, SiGe, SiC, GaAs, InAs, InP, and/or the like. In some embodiments, the substrate 110 may include a conductive area, for example, an impurity-doped well, or an impurity-doped structure.

The device isolation layer 212 may include an insulator layer, such as an oxide layer a nitride layer, or a combination thereof. A first buffer insulating layer 214A and a second buffer insulating layer 214B may be sequentially disposed on an upper surface of the substrate 110. Each of the first buffer insulating layer 214A and the second buffer insulating layer 214B may include, e.g., silicon oxide, silicon oxynitride, or silicon nitride.

A plurality of word line trenches extending in the first horizontal direction X may be disposed in the substrate 110, and a buried gate structure 220 may be disposed in each of the plurality of word line trenches. The buried gate structure 220 may include a gate dielectric layer 222, a gate electrode 224, and a word line capping layer 226 disposed in each of the plurality of word line trenches. A plurality of gate electrodes 224 may correspond to a plurality of word lines extending in the first horizontal direction X.

A plurality of gate dielectric layers 222 may each include an insulator layer, such as a silicon oxide layer, a silicon nitride layer, a silicon oxynitride layer, an oxide/nitride/oxide (ONO) layer, a high-k dielectric layer, and/or the like. A plurality of gate electrodes 224 may each include a conductor, such as Ti, TiN, Ta, TaN, W, WN, TiSiN, WSiN, a combination thereof, and/or the like. A plurality of word line capping layers 226 may each include an insulator layer, such as a silicon oxide layer, a silicon nitride layer, a silicon oxynitride layer, a combination thereof, and/or the like.

A plurality of bit line contact holes DCH may extend into the substrate 110 through the first buffer insulating layer 214A and the second buffer insulating layer 214B, and a plurality of bit line contacts DC may be respectively formed in the plurality of bit line contact holes DCH. The plurality of bit line contacts DC may be respectively connected to a plurality of active areas AC. The plurality of bit line contacts DC may each include Si, Ge, W, WN, Co, Ni, Al, Mo, Ru, Ti, TiN, Ta, TaN, Cu, or a combination thereof.

A plurality of bit lines BL may extend long in the second horizontal direction Y on the substrate 110 and the plurality of bit line contacts DC. Each of the plurality of bit lines BL may be connected to the active area AC through the bit line contact DC.

In some embodiments, each of the plurality of bit lines BL may include a lower conductive layer 232 and an upper conductive layer 234.

The lower conductive layer 232 may extend in the second horizontal direction Y on the second buffer insulating layer 214B. The lower conductive layer 232 may be disposed on an upper surface of the bit line contact DC. The lower conductive layer 232 may include at least one of Si, Ge, W, WN, Co, Ni, Al, Mo, Ru, Ti, TiN, Ta, TaN, Cu, cobalt silicide, nickel silicide, or tungsten silicide.

The upper conductive layer 234 may be disposed on an upper surface of the lower conductive layer 232 and extend in the second horizontal direction Y. In some embodiments, the upper conductive layer 234 may include any one of tungsten (W), ruthenium (Ru), molybdenum (Mo), titanium (Ti), rhodium (Ro), iridium (Ir), or an alloy thereof.

A plurality of bit line capping layers 240 may be respectively disposed on the plurality of bit lines BL. The bit line capping layer 240 may include a plurality of insulating layers, and each of the insulating layers included in the bit line capping layer 240 may include at least one of silicon nitride, silicon oxide, or silicon oxynitride.

A plurality of buried contacts may be disposed between the plurality of bit lines BL. A bottom portion of each of the plurality of buried contacts may be in contact with the active area AC, and a plurality of landing pads LP may be respectively disposed on the plurality of buried contacts. In some embodiments, a plurality of buried contacts may each include doped polysilicon, and a plurality of landing pads LP may each include metal, metal nitride, conductive polysilicon, or a combination thereof. The plurality of landing pads LP may be electrically insulated from each other by an insulating pattern 252 surrounding the plurality of landing pads LP. The insulating pattern 252 may include at least one of silicon nitride, silicon oxide, or silicon oxynitride.

An etching stop layer 254 may be disposed on the insulating pattern 252, and the lower electrode 132 may be disposed through the etching stop layer 254. The bottom surface of the lower electrode 132 may be disposed on an upper surface of the landing pad LP. In some embodiments, the landing pad LP may correspond to the first conductive pattern 122 shown in FIG. 2.

Generally, after forming a capacitor structure in a cell array area, a peripheral circuit insulating layer is formed in a peripheral circuit area, and a peripheral circuit contact through the peripheral circuit insulating layer is formed. However, as integration of an integrated circuit (IC) device increases, a height of a capacitor and a height of the peripheral circuit contact increases to compensate, and a level difference in an upper surface between the cell array area and the peripheral circuit area increases, which causes an increase in a grinding thickness of the peripheral circuit insulating layer in a chemical mechanical plashing (CMP) process and/or a defocus defect in a lithography process.

According to some embodiments, after forming the mold stack MST, a portion of the mold stack MST on the cell array area MCA and a portion of the mold stack MST on the peripheral circuit area PCA may be separated from each other by forming the dam structure DA, and the lower electrode 132 may be formed by using the mold stack MST on the cell array area MCA. The portion of the mold stack MST on the peripheral circuit area PCA remains as the peripheral circuit insulating layer PI, and thus, there is no need to additionally form a peripheral circuit insulating layer and/or to perform the CMP process.

In addition, the level difference in an upper surface between the cell array area MCA and the peripheral circuit area PCA is relatively small, and thus, a defocus defect in the lithography process may be reduced or prevented. In addition, the peripheral circuit contact 160 and the lower electrode 132 are simultaneously formed, and thus, an etching process time for forming the first upper contact 172 and the second upper contact 174 may be reduced, thereby minimizing the thickness of the upper electrode 136. Therefore, defects in the manufacturing process of the semiconductor device 100 may be prevented.

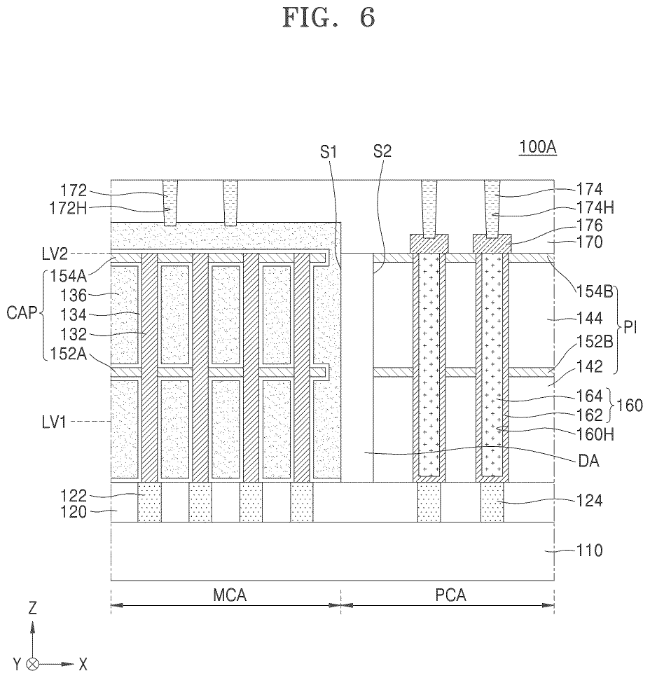

FIG. 6 is a cross-sectional view illustrating a semiconductor device 100A according to some embodiments.

Referring to FIG. 6, a contact pad 176 may be disposed on the peripheral circuit insulating layer PI, and a second upper contact 174 may be disposed on the contact pad 176. In some embodiments, the contact pad 176 may have a greater horizontal width than that of the peripheral circuit contact 160 to cover the entire upper surface of the peripheral circuit contact 160. Accordingly, even when a mask pattern is misaligned in a process of forming a second contact hole 174H by etching a part of the upper insulating layer 170, a sufficient electrical contact between the second upper contact 174 and the contact pad 176 may be ensured.

Also, in some embodiments, a difference between a height of the first upper contact 172 in the vertical direction Z and a height of the second upper contact 174 in the vertical direction Z is reduced, and thus, an etching process time for forming the first upper contact 172 and the second upper contact 174 may be reduced, thereby minimizing a thickness of the upper electrode 136.

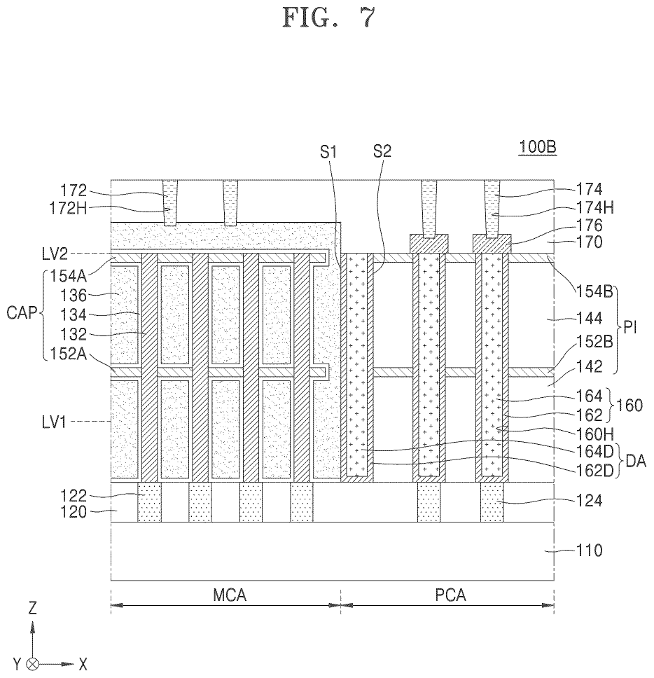

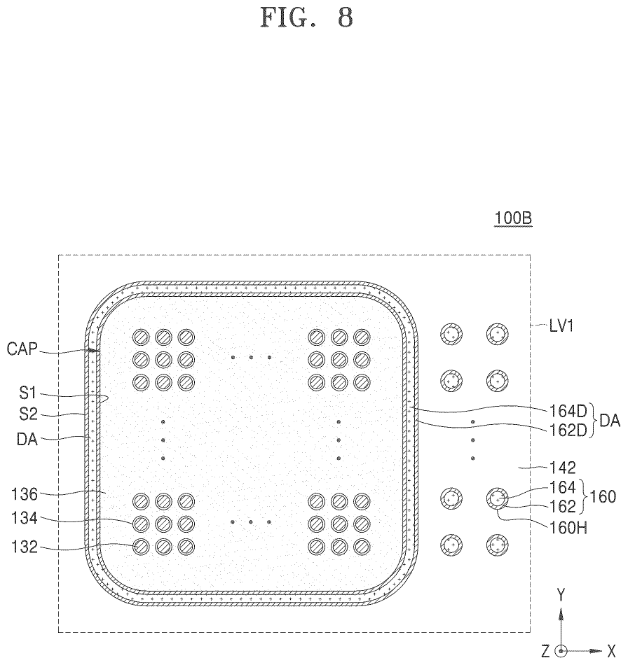

FIG. 7 is a cross-sectional view illustrating a semiconductor device 100B according to some embodiments. FIG. 8 is a plan layout diagram at the first vertical level LV1 of FIG. 7.

Referring to FIGS. 7 and 8, the dam structure DA may include a contact plug 164D, and conductive barrier layers 162D disposed on both sidewalls and a bottom surface of the contact plug 164D. In some embodiments, the conductive barrier layer 162D may include at least one of Ti, TiN, Ta, TaN, W, WN, TiSiN, or WSiN. In some embodiments, the contact plug 164D may include at least one of Ti, TiN, Ta, TaN, W, WN, TiSiN, or WSiN.

In some embodiments, the dam structure DA may be formed by forming a dam opening DAH in the mold stack MST and then sequentially forming the conductive barrier layer 162D and the contact plug 164D on an inner wall of the dam opening DAH. In some embodiments, the dam structure DA may be simultaneously formed in a process of forming the peripheral circuit contact 160 in the peripheral circuit contact hole 160H.

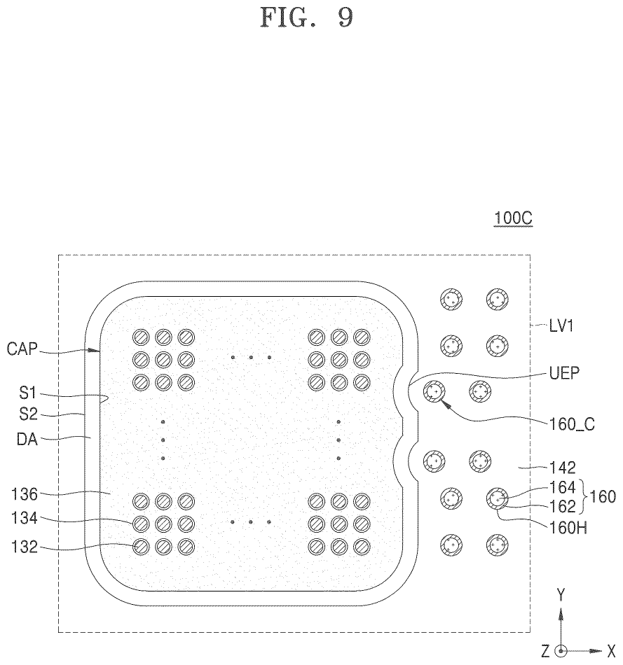

FIG. 9 is a plan layout diagram illustrating a semiconductor device 100C according to some embodiments.

Referring to FIG. 9, the dam structure DA may include an uneven portion UEP. In some embodiments, in a planar view, the uneven portion UEP may refer to a portion of the dam structure DA where the inner wall S1 or the outer wall S2 protrudes or is recessed. For example, the uneven portion UEP may refer to a portion where the inner wall S1 of the dam structure DA protrudes toward the upper electrode 136, or a portion where the outer wall S2 is recessed toward the upper electrode 136.

In some embodiments, when the peripheral circuit contact 160 is disposed adjacent to the dam structure DA, the uneven portion UEP of the dam structure DA may be disposed adjacent to the peripheral circuit contact 160. In some embodiments, when the partial peripheral circuit contact 160 disposed closest to the dam structure DA is referred to as a closest peripheral circuit contact 160_C, the uneven portion UEP may have a shape concentric with the closest peripheral circuit contact 160_C. In some embodiments, both the uneven portion UEP of the inner wall S1 of the dam structure DA and the uneven portion UEP of the outer wall S2 of the dam structure DA may have the shape concentric with the closest peripheral circuit contact 160_C. The uneven portion UEP has the shape concentric with the closest peripheral circuit contact 160_C, and thus, a sufficient separation distance or sufficient electrical insulation between the peripheral circuit contact 160 and the upper electrode 136 may be secured.

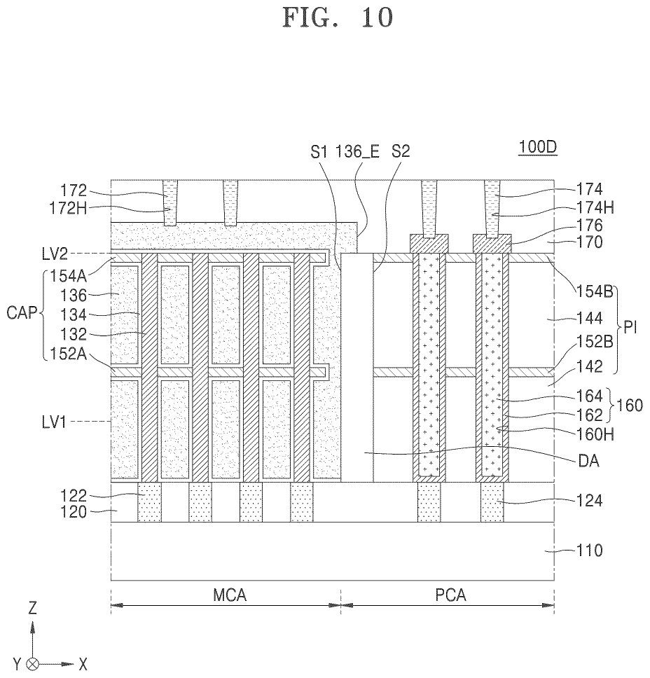

FIG. 10 is a cross-sectional view illustrating a semiconductor device 100D according to some embodiments.

Referring to FIG. 10, the upper electrode 136 may include an edge portion 136_E disposed on an upper surface of the dam structure DA. The edge portion 136_E of the upper electrode 136 may refer to a portion of the upper electrode 136 remaining on the dam structure DA in a process of removing a part of the upper electrode 136 formed on the dam structure DA and the peripheral circuit insulating layer PI.

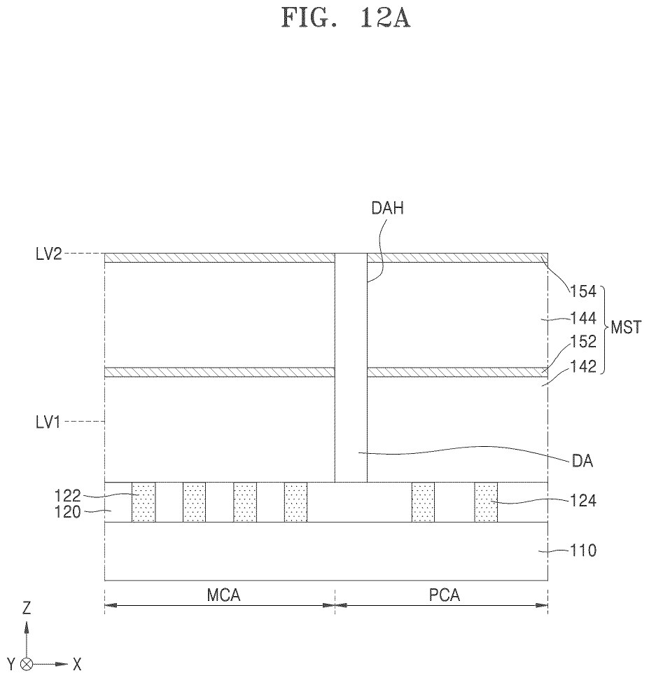

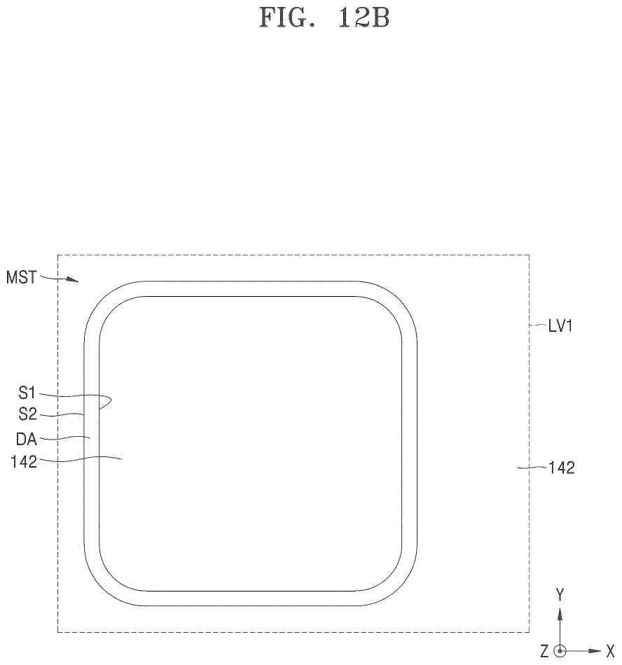

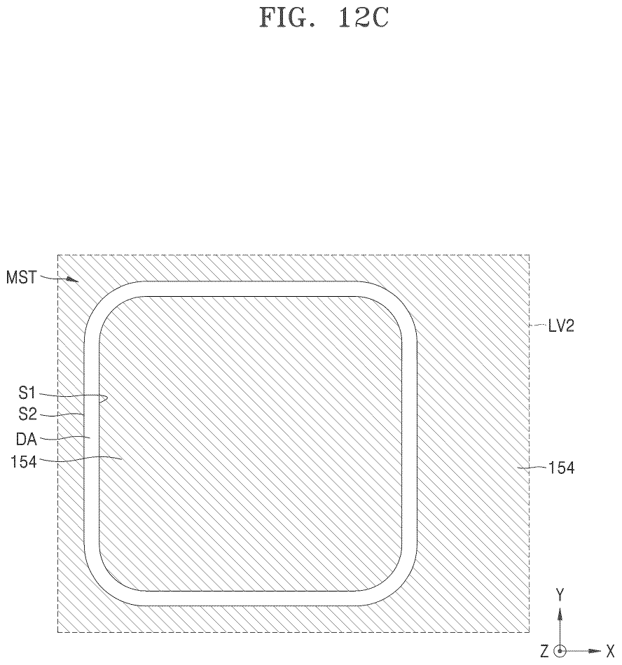

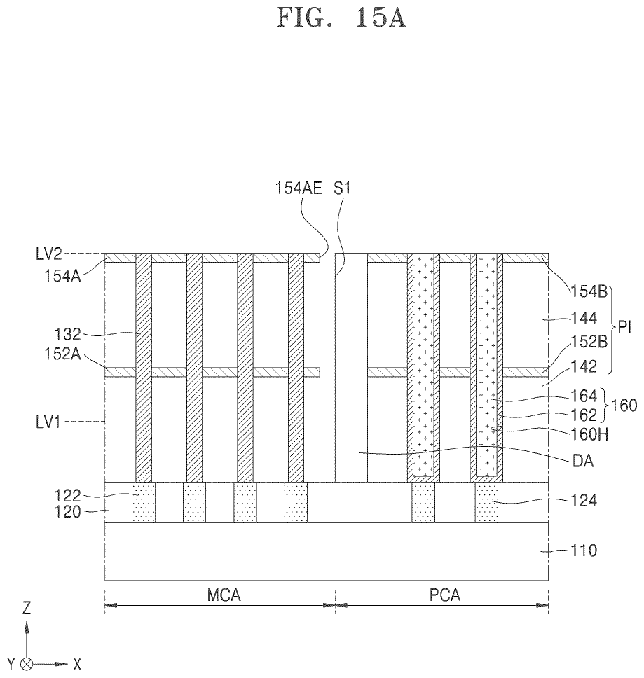

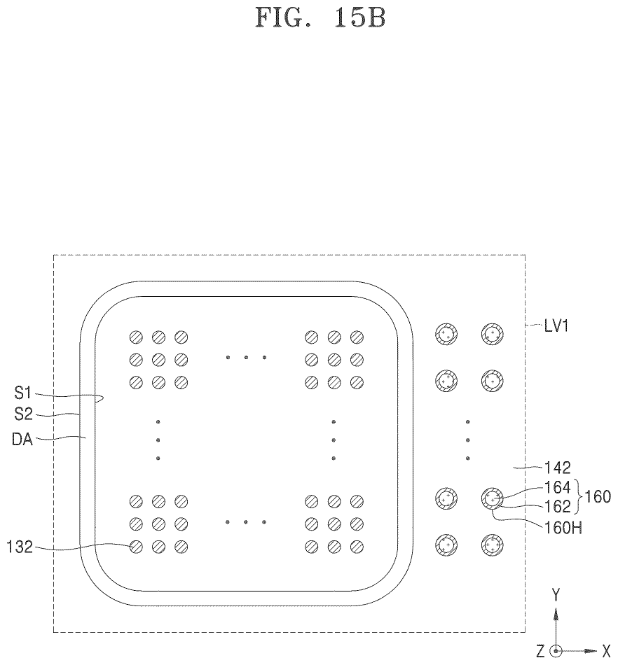

FIGS. 11, 12A, 13, 14, 15A, and 16 to 19 are cross-sectional views illustrating a method of manufacturing the semiconductor device 100 according to some embodiments. FIGS. 12B and 15B are plan layout diagrams at the first vertical level LV1 of FIGS. 12A and 15A. FIGS. 12C and 15C are plan layout diagrams at the second vertical level LV2 of FIGS. 12A and 15A.

Referring to FIG. 11, the lower structure 120, the first conductive pattern 122, and the second conductive pattern 124 are formed on the substrate 110.

In some embodiments, the cell transistor CTR described with reference to FIG. 5 may be formed on the cell array area MCA of the substrate 110. For example, the first conductive pattern 122 may correspond to the landing pad LP described with reference to FIG. 5, and the lower structure 120 may correspond to a structure including the bit line BL, the bit line capping layer 240, the bit line contact DC, the insulating pattern 252, and the etching stop layer 254 described with reference to FIG. 5.

The mold stack MST may be formed by sequentially forming the first mold insulating layer 142, a first supporter layer 152, a second mold insulating layer 144, and a second supporter layer 154 on the lower structure 120.

The mold stack MST may be disposed to entirely cover the cell array area MCA and the peripheral circuit area PCA.

In some embodiments, the first mold insulating layer 142 and the second mold insulating layer 144 may each include silicon oxide, silicon nitride, silicon carbide, silicon boron nitride, and/or a combination thereof.

In some embodiments, the first supporter layer 152 may be formed using a material having etch selectivity with respect to the first mold insulating layer 142, and the second supporter layer 154 may be formed using a material having etch selectivity with respect to the second mold insulating layer 144.

Referring to FIGS. 12A to 12C, a mask pattern is formed on the mold stack MST, and the dam opening DAH is formed by removing a part of the mold stack MST by using the mask pattern as an etching mask in, e.g., a plasma etching process.

In some embodiments, the dam opening DAH may be formed at a boundary between the cell array area MCA and the peripheral circuit area PCA, or at an edge portion of the peripheral circuit area PCA adjacent to the cell array area MCA.

Thereafter, the dam structure DA may be formed in the dam opening DAH. In at some embodiments, the dam structure DA may be formed using, e.g., silicon nitride, silicon carbide, silicon boron nitride, and/or a combination thereof.

In some embodiments, the dam structure DA may have an upper surface disposed at the same level as an upper surface of the mold stack MST, and for example, the upper surface of the dam structure DA may be disposed at the same level as an upper surface of the second supporter layer 154.

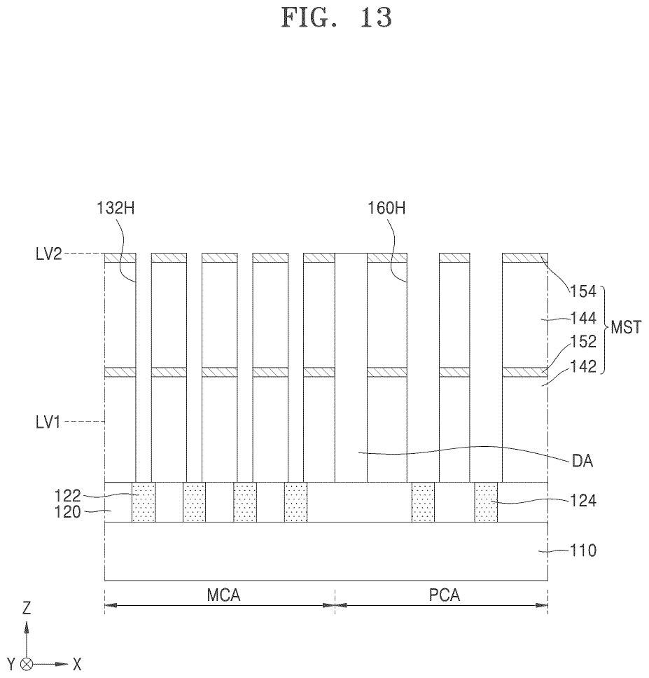

Referring to FIG. 13, a mask pattern may be formed on the upper surface of the mold stack MST, a lower electrode hole 132H may be formed by removing a part of the mold stack MST on the cell array area MCA by using the mask pattern as an etching mask, and the peripheral circuit contact hole 160H may be formed by removing a part of the mold stack MST on the peripheral circuit area PCA.

In some embodiments, a process of forming the lower electrode hole 132H and a process of forming the peripheral circuit contact hole 160H may be performed in the same stage. In some embodiments, the lower electrode hole 132H may be formed first, and then, the peripheral circuit contact hole 160H may be formed. In some embodiments, the peripheral circuit contact hole 160H may be formed, and then, the lower electrode hole 132H may be formed.

In some embodiments, the lower electrode hole 132H may extend in the vertical direction Z such that an upper surface of the first conductive pattern 122 may be exposed on a bottom portion of the lower electrode hole 132H. In some embodiments, the peripheral circuit contact hole 160H may extend in the vertical direction Z such that an upper surface of the second conductive pattern 124 may be exposed on a bottom portion of the peripheral circuit contact hole 160H.

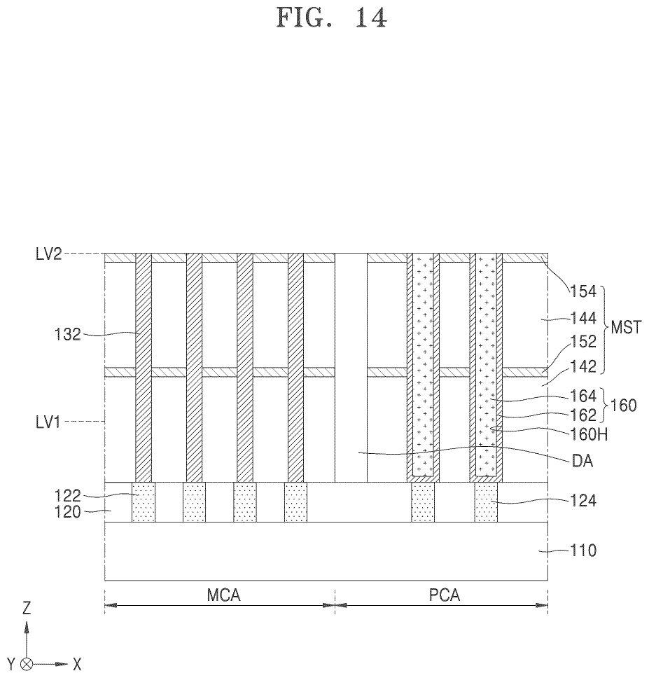

Referring to FIG. 14, the lower electrode 132 may be formed by filling a conductive material in the lower electrode hole 132H, and the peripheral circuit contact 160 may be formed by filling a conductive material in the peripheral circuit contact hole 160H.

In some embodiments, the lower electrode 132 may be formed in the lower electrode hole 132H, and the conductive barrier layer 162 may be formed in the peripheral circuit contact hole 160H. For example, the lower electrode 132 may be formed in the same process as the process of forming the conductive barrier layer 162. For example, the lower electrode 1132 may include the same material as the conductive barrier layer 162. After the conductive barrier layer 162 is formed, the contact plug 164 filling the inside of the peripheral circuit contact hole 160H may be formed.

Referring to FIGS. 15A to 15C, after a mask pattern is formed on the mold stack MST, the plurality of openings 154AH may be formed in the second supporter layer 154 by using the mask pattern as an etching mask. The second supporter layer 154 may have the end portion 154AE spaced apart from the dam structure DA by a certain distance.

Thereafter, the second mold insulating layer 144 exposed between the plurality of openings 154AH and the end portion 154AE of the second supporter layer 154 and the dam structure DA may be removed. A process of removing the second mold insulating layer 144 may be a wet etching process. In the process of removing the second mold insulating layer 144, a portion of the second mold insulating layer 144 disposed on the cell array area MCA may be removed, and an upper side of a sidewall of the lower electrode 132 may be exposed.

Thereafter, a plurality of openings may be formed by removing a part of the first supporter layer 152. In addition, the first supporter layer 152 may have an end portion spaced apart from the dam structure DA by a certain distance.

Thereafter, the first mold insulating layer 142 exposed between the plurality of openings of the first supporter layer 152 and the end portion of the first supporter layer 152 and the dam structure DA may be removed. A process of removing the first mold insulating layer 142 may be a wet etching process. In the process of removing the first mold insulating layer 142, a part of the first mold insulating layer 142 disposed on the cell array area MCA may be removed, and a lower side of the sidewall of the lower electrode 132 may be exposed.

While the first mold insulating layer 142 and the second mold insulating layer 144 are removed from the cell array area MCA, the first supporter layer 152 and the second supporter layer 154 may remain without being removed, and may be spaced apart from each other in the vertical direction on the sidewall of the lower electrode 132. The first supporter layer 152 and the second supporter layer 154 remaining in the cell array area MCA may be respectively referred to as the first cell supporter pattern 152A and the second cell supporter pattern 154A. The end portion of the first cell supporter pattern 152A and the end portion 154AE of the second cell supporter pattern 154A may be spaced apart from the inner wall S1 of the dam structure DA by a certain distance without contacting the dam structure DA.

While the first mold insulating layer 142 and the second mold insulating layer 144 are removed from the cell array area MCA, a portion of the mold stack MST (e.g., the first mold insulating layer 142 and the second mold insulating layer 144) disposed on the peripheral circuit area PCA may be covered by the dam structure DA and may not be exposed to an etchant or an etching atmosphere. Accordingly, the portion of the mold stack MST disposed on the peripheral circuit area PCA may remain without being removed, and may be referred to as the peripheral circuit insulating layer PI.

The peripheral circuit insulating layer PI may include the first mold insulating layer 142, the first supporter layer 152B, the second mold insulating layer 144, and the second supporter layer 154B, the first supporter layer 152B may be disposed on the entire upper surface of the first mold insulating layer 142, the second mold insulating layer 144 may be disposed on the entire upper surface of the first supporter layer 152B, and the second supporter layer 154B may be disposed on the entire upper surface of the second mold insulating layer 144.

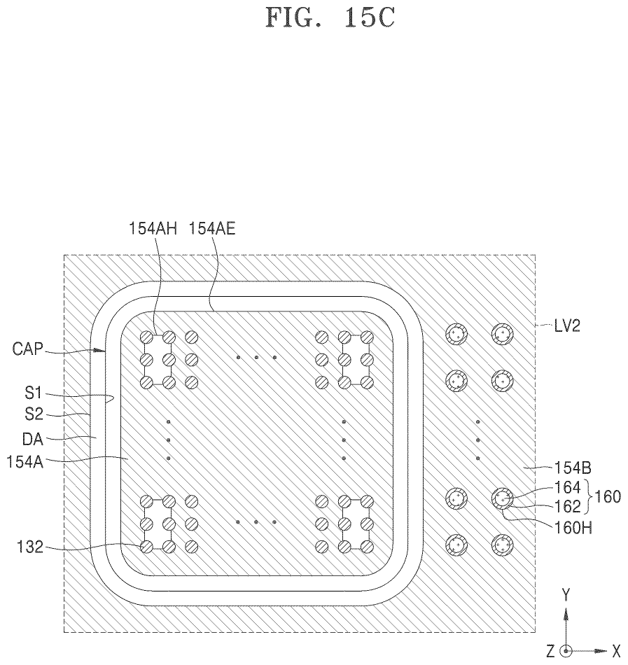

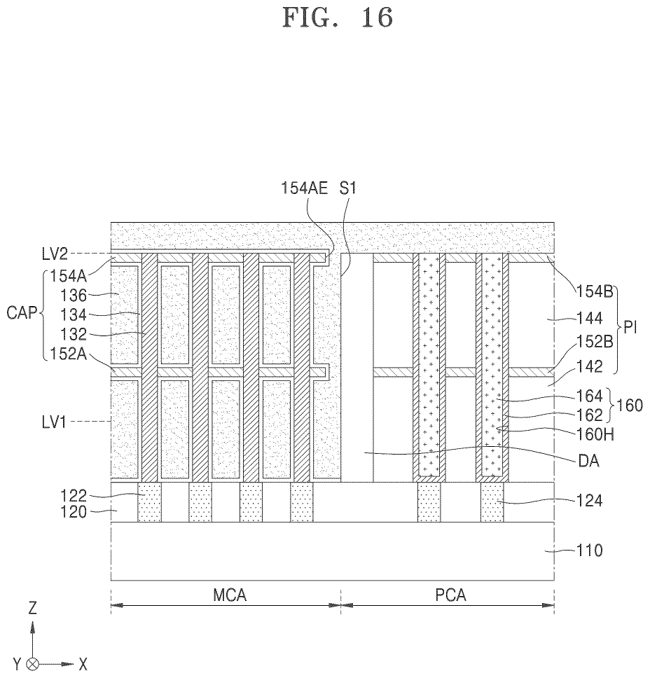

Referring to FIG. 16, the capacitor dielectric layer 134 may be formed on a sidewall of the lower electrode 132, an upper surface and a bottom surface of the first cell supporter pattern 152A, and an upper surface and a bottom surface of the second cell supporter pattern 154A.

Thereafter, the upper electrode 136 may be formed on the capacitor dielectric layer 134.

The upper electrode 136 may fill the inside of space defined by the inner wall S1 of the dam structure DA. The upper electrode 136 may be in contact with the inner wall S1 of the dam structure DA, and may be formed at a certain height on the upper surface of the second cell supporter pattern 154A and an upper surface of the peripheral circuit insulating layer PI.

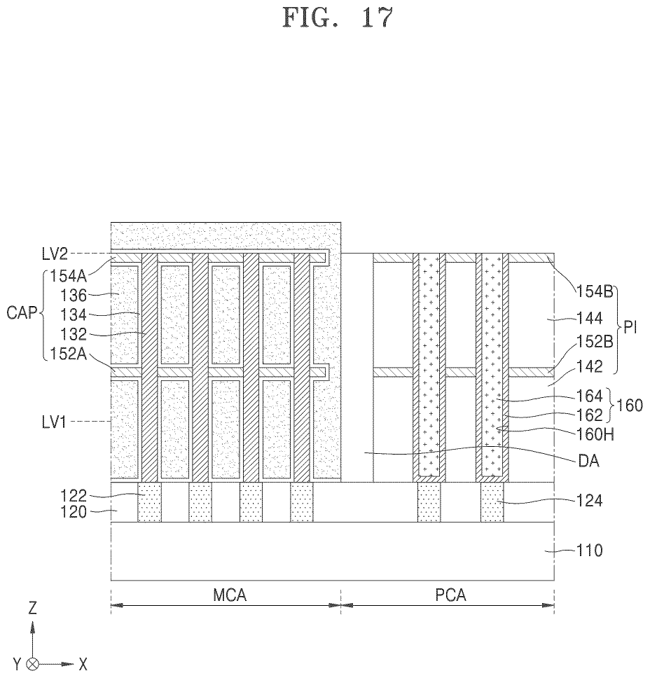

Referring to FIG. 17, a mask pattern may be formed on the upper electrode 136, and a part of the upper electrode 136 disposed on the peripheral circuit insulating layer PI may be removed using the mask pattern as an etching mask.

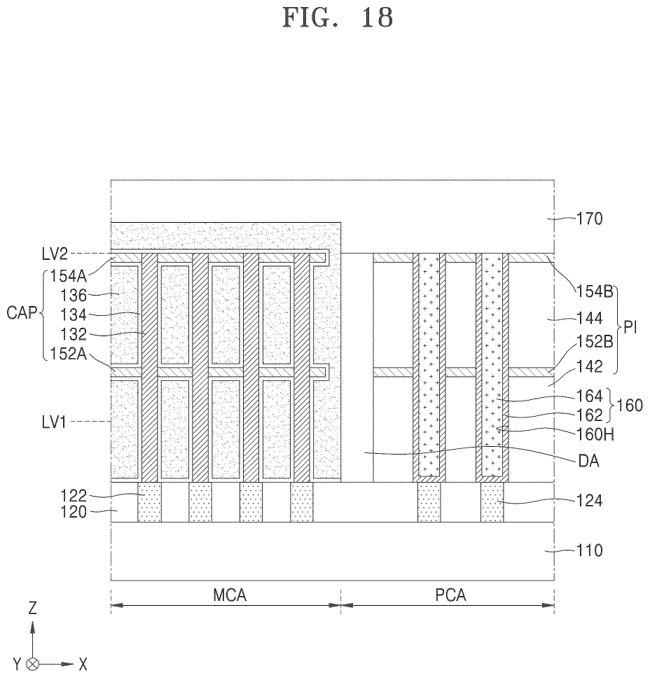

Referring to FIG. 18, the upper insulating layer 170 may be formed on the upper electrode 136, the dam structure DA, and the peripheral circuit insulating layer PI. The upper insulating layer 170 may be formed to entirely cover the cell array area MCA and the peripheral circuit area PCA, and may have a flat upper surface over the entire cell array area MCA and the peripheral circuit area PCA.

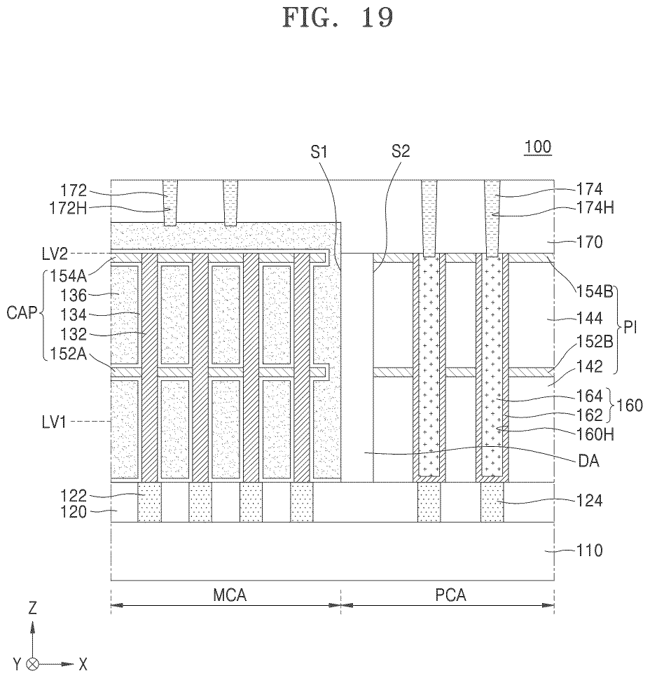

Referring to FIG. 19, a mask pattern may be formed on the upper insulating layer 170, and first contact holes 172H and second contact holes 174H may be formed using the mask pattern as an etching mask.

Thereafter, the first upper contact 172 may be formed in the first contact hole 172H, and the second upper contact 174 may be formed in the second contact hole 174H.

The first upper contact 172 may be electrically connected to the upper electrode 136, and the second upper contact 174 may be electrically connected to the peripheral circuit contact 160.

The semiconductor device 100 may be completed by performing the above-described method.

Generally, after forming a capacitor structure in a cell array area, a peripheral circuit insulating layer is formed in a peripheral circuit area, and a peripheral circuit contact through the peripheral circuit insulating layer is formed. However, as integration of an IC device increases, a height of a capacitor and a height of the peripheral circuit contact increases to compensate, and a level difference in an upper surface between the cell array area and the peripheral circuit area increases, which causes an increase in a grinding thickness of the peripheral circuit insulating layer in a CMP process or a defocus defect in a lithography process.

According to the above embodiments, after forming the mold stack MST, a portion of the mold stack MST on the cell array area MCA and a portion of the mold stack MST on the peripheral circuit area PCS may be separated from each other by forming the dam structure DA, and the lower electrode 132 may be formed by using the mold stack MST on the cell array area MCA. The portion of the mold stack MST on the peripheral circuit area PCS remains as the peripheral circuit insulating layer PI, and thus, there is no need to additionally form a peripheral circuit insulating layer and perform the CMP process.

In addition, the level difference in an upper surface between the cell array area MCA and the peripheral circuit area PCA is relatively small, and thus, a defocus defect in the lithography process may be prevented and/or mitigated. In addition, the peripheral circuit contact 160 and the lower electrode 132 are simultaneously formed, and thus, an etching process time for forming the first upper contact 172 and the second upper contact 174 may be reduced, thereby minimizing the thickness of the upper electrode 136. Therefore, defects in the manufacturing process of the semiconductor device 100 may be prevented.

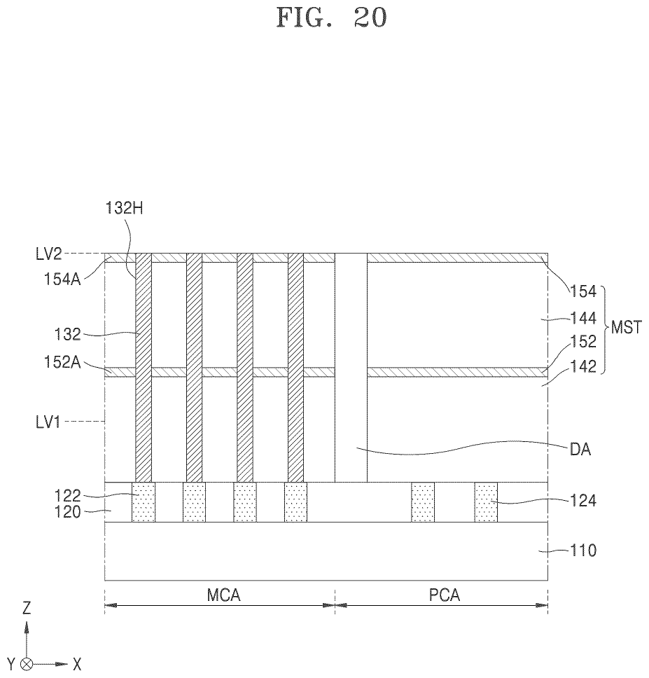

FIGS. 20 and 21 are cross-sectional views illustrating a method of manufacturing the semiconductor device 100 according to some embodiments. The manufacturing method described with reference to FIGS. 20 and 21 may be similar to the manufacturing method described with reference to FIGS. 11 to 19, except that the lower electrode 132 is formed and then, the peripheral circuit contact 160 is formed.

First, a part of the mold stack MST may be removed, and the dam structure DA may be formed by performing a process described with reference to FIGS. 11 to 12C.

Referring to FIG. 20, the lower electrode hole 132H may be formed by removing a part of the mold stack MST from the cell array area MCA. Thereafter, the lower electrode 132 may be formed using a conductive material in the lower electrode hole 132H.

Referring to FIG. 21, the peripheral circuit contact hole 160H may be formed by removing a part of the mold stack MST from the peripheral circuit area PCA. Thereafter, the peripheral circuit contact 160 may be formed using a conductive material in the peripheral circuit contact hole 160H.

Then, the semiconductor device 100 may be completed by performing the processes described with reference to FIGS. 15A to 19.

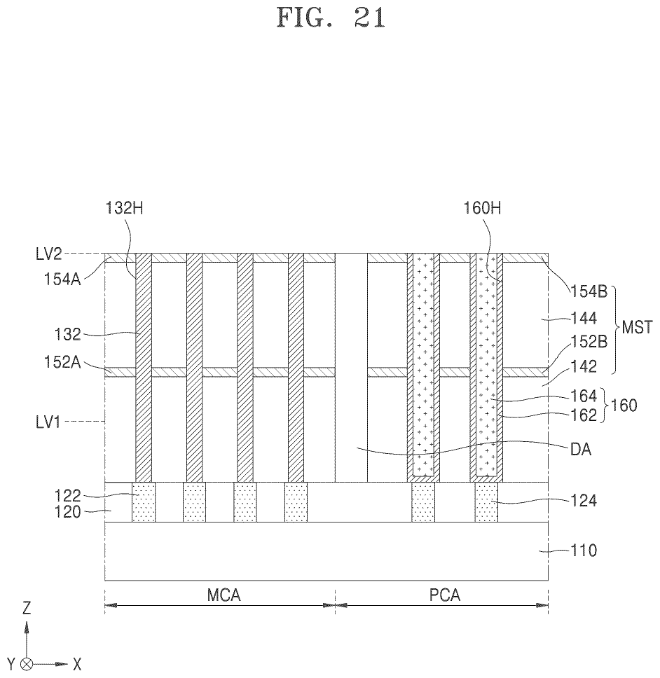

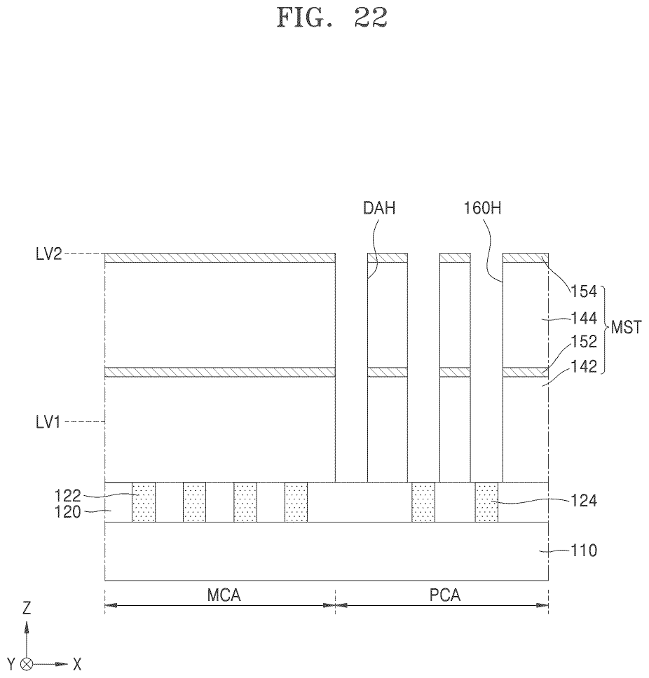

FIGS. 22 to 26 are cross-sectional views illustrating a method of manufacturing the semiconductor device 100B according to some embodiments.

Referring to FIG. 22, the mold stack MST may be formed on the lower structure 120, and the dam opening DAH and the peripheral circuit contact hole 160H may be formed by removing a part of the mold stack MST.

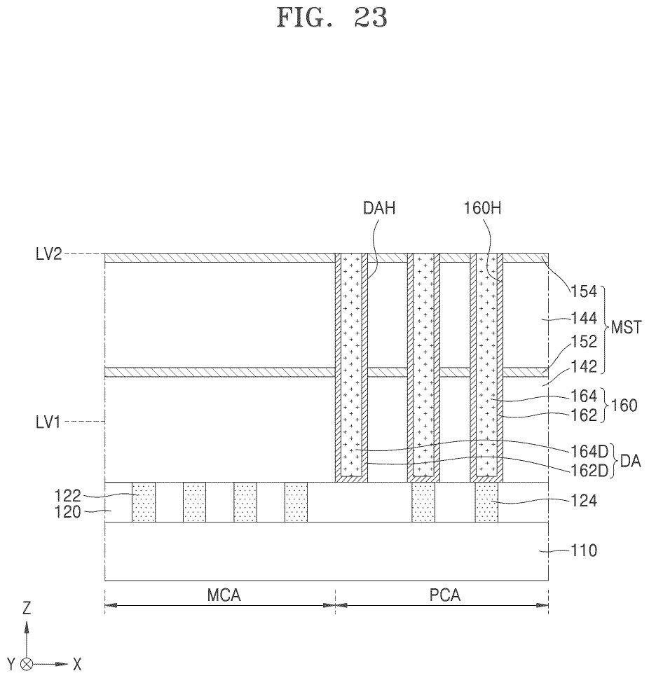

Referring to FIG. 23, the dam structure DA and the peripheral circuit contact 160 may be formed in the dam opening DAH and the peripheral circuit contact hole 160H by using conductive materials, respectively.

In some embodiments, the dam structure DA may include the conductive barrier layer 162D disposed on an inner wall of the dam opening DAH and the contact plug 164D filling the inside of the dam opening DAH. In some embodiments, the peripheral circuit contact 160 may include the conductive barrier layer 162 disposed on an inner wall of the peripheral circuit contact hole 160H and the contact plug 164 filling the inside of the peripheral circuit contact hole 160H.

In some embodiments, a process of forming the conductive barrier layer 162D on the inner wall of the dam opening DAH and a process of forming the conductive barrier layer 162 on the inner wall of the peripheral circuit contact hole 160H may be simultaneously performed. Thereafter, the process of forming the contact plug 164D on the inner wall of the dam opening DAH and the process of forming ▭ on the inner wall of the peripheral circuit contact hole 160H may be simultaneously performed.

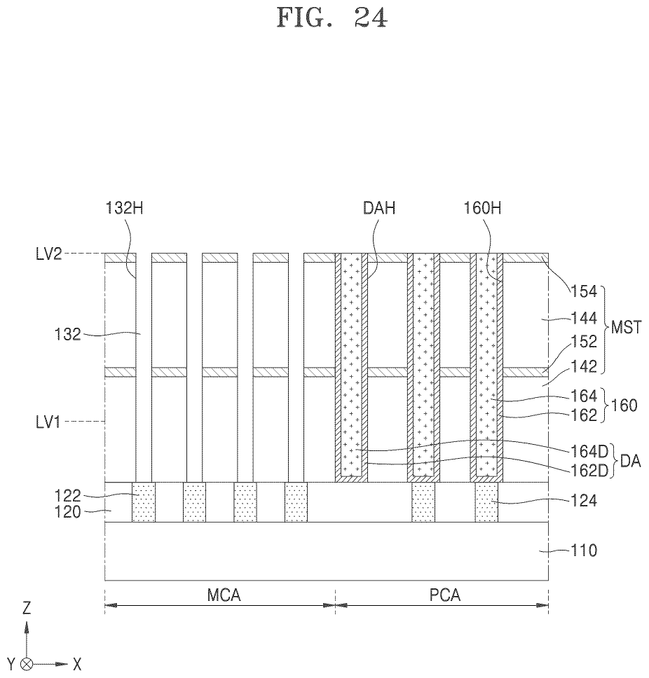

Referring to FIG. 24, the lower electrode hole 132H may be formed by removing a part of the mold stack MST from the cell array area MCA. The lower electrode hole 132H may expose the plurality of first conductive patterns 122.

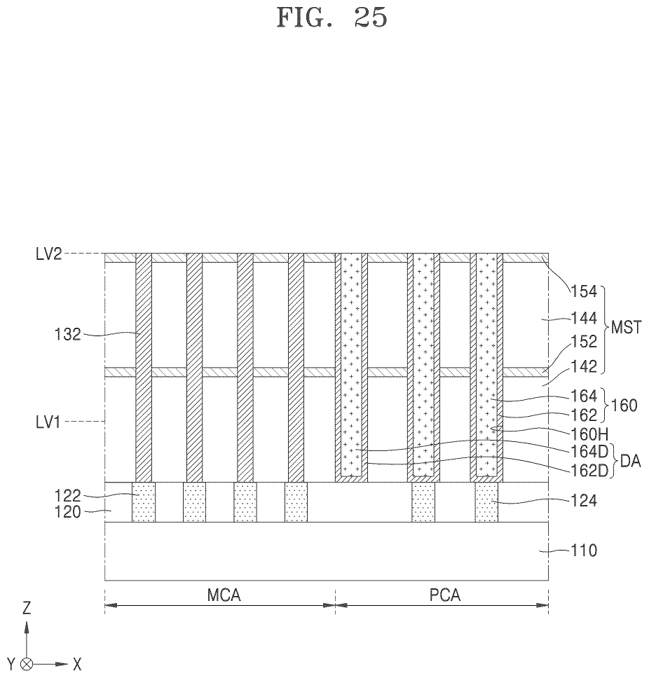

Referring to FIG. 25, the lower electrode 132 may be formed in the lower electrode hole 132H using a conductive material.

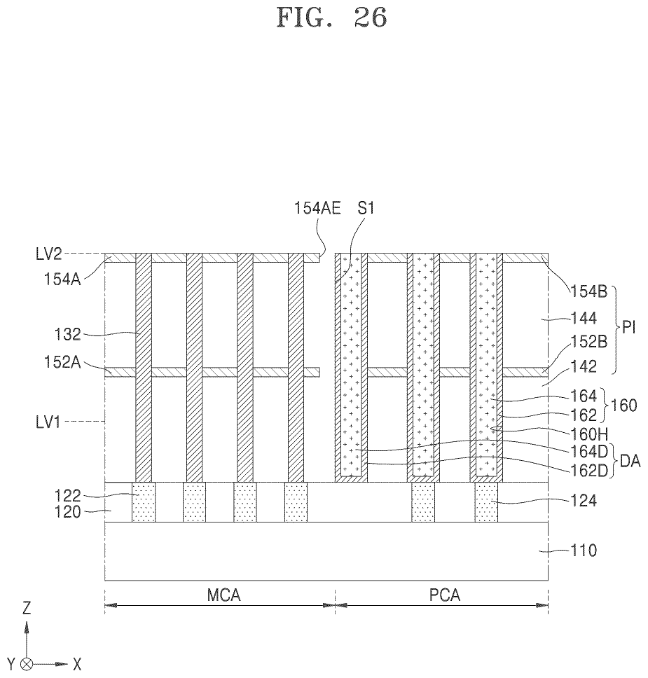

Referring to FIG. 26, a plurality of openings may be formed by removing a part of the second supporter layer 154 in the cell array area MCA. In addition, a part of the second supporter layer 154 adjacent to the dam structure DA may be removed together so that the second supporter layer 154 may have the end portion 154AE spaced apart from the dam structure DA by a certain distance.

Thereafter, the second mold insulating layer 144 exposed between the plurality of openings and the end portion 154AE of the second supporter layer 154 and the dam structure DA may be removed.

Thereafter, a plurality of openings may be formed by removing a part of the first supporter layer 152. In addition, a part of the first supporter layer 152 adjacent to the dam structure DA may be removed together so that the first supporter layer 152 may have an end portion spaced apart from the dam structure DA by a certain distance.

Thereafter, the first mold insulating layer 142 exposed between the plurality of openings of the first supporter layer 152 and the end portion of the first supporter layer 152 and the dam structure DA may be removed.

After the first mold insulating layer 142 and the second mold insulating layer 144 are removed, a sidewall of the lower electrode 132 may be exposed.

While the first mold insulating layer 142 and the second mold insulating layer 144 are removed from the cell array area MCA, a portion of the mold stack MST (e.g., the first mold insulating layer 142 and the second mold insulating layer 144) disposed on the peripheral circuit area PCA may be covered by the dam structure DA and may not be exposed to an etchant or an etching atmosphere. Accordingly, the portion of the mold stack MST disposed on the peripheral circuit area PCA may remain without being removed, and may be referred to as the peripheral circuit insulating layer PI.

Hereinafter, the semiconductor device 100B may be completed by performing the processes described with reference to FIGS. 16 to 19.

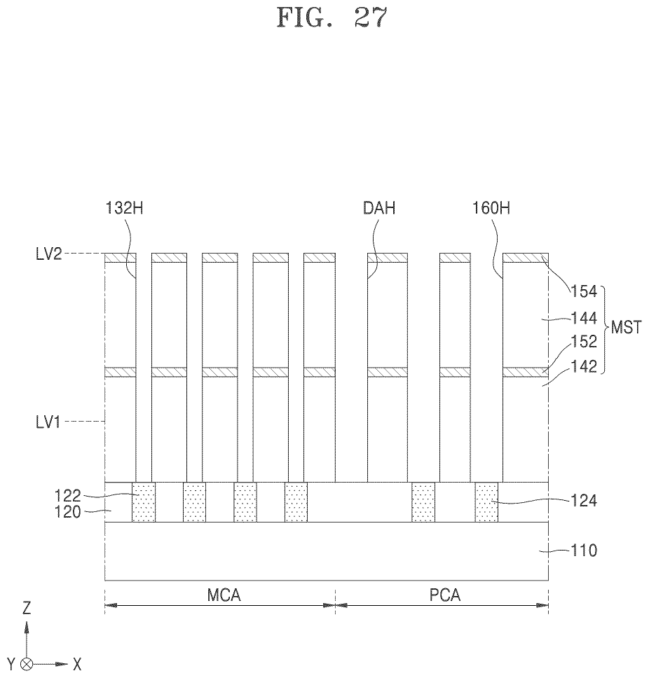

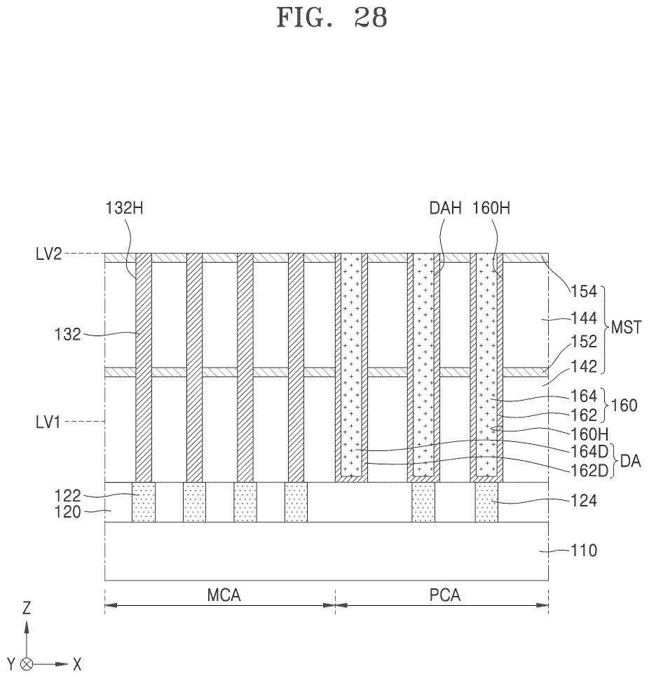

FIGS. 27 and 28 are cross-sectional views illustrating a method of manufacturing the semiconductor device 100B according to some embodiments. The manufacturing method described with reference to FIGS. 27 and 28 is similar to the manufacturing method described with reference to FIGS. 22 to 26, except that the lower electrode 132, the dam structure DA, and the peripheral circuit contact 160 are formed in the same process.

Referring to FIG. 27, the lower electrode hole 132H, the dam opening DAH, and the peripheral circuit contact hole 160H may be formed by removing parts of the mold stack MST.

Referring to FIG. 28, the lower electrode 132, the dam structure DA, and the peripheral circuit contact 160 may be formed using a conductive material in each of the lower electrode hole 132H, the dam opening DAH, and the peripheral circuit contact hole 160H.

Hereinafter, the semiconductor device 100B may be completed by performing the processes described with reference to FIGS. 16 to 19.

While the inventive concepts have been particularly shown and described with reference to embodiments thereof, it will be understood that various changes in form and details may be made therein without departing from the spirit and scope of the following claims.

What is claimed is:

1. A semiconductor device comprising:
a substrate comprising a cell array area and a peripheral circuit area;
a capacitor structure on the cell array area of the substrate;
a dam structure surrounding the capacitor structure in a planar view;
a peripheral circuit insulating layer on the peripheral circuit area of the substrate and on a sidewall of the dam structure, the peripheral circuit insulating layer comprising
a first mold insulating layer,
a first supporter layer on the first mold insulating layer, and
a second mold insulating layer on the first supporter layer such that the first supporter layer is between the first and second mold insulating layers; and
a peripheral circuit contact on the peripheral circuit area of the substrate, the peripheral circuit contact extending through the peripheral circuit insulating layer in a vertical direction perpendicular to an upper surface of the substrate.

2. The semiconductor device of claim 1, wherein the capacitor structure includes:
a plurality of lower electrodes extending in the vertical direction;
a first cell supporter pattern on a part of sidewalls of the plurality of lower electrodes;
a capacitor dielectric layer on the sidewalls of the plurality of lower electrodes and on an upper surface and a bottom surface of the first cell supporter pattern; and
an upper electrode on the capacitor dielectric layer and covering the plurality of lower electrodes and the first cell supporter pattern.

3. The semiconductor device of claim 2, wherein an upper surface of the first supporter layer is at a same vertical level as the upper surface of the first cell supporter pattern.

4. The semiconductor device of claim 2, wherein the first supporter layer includes a same material as the first cell supporter pattern.

5. The semiconductor device of claim 2, wherein
the first cell supporter pattern includes a plurality of openings, and
the first supporter layer entirely covers an upper surface of the first mold insulating layer.

6. The semiconductor device of claim 2, further comprising:
a first upper contact on the upper electrode such that the first upper contact is electrically connected to the upper electrode; and
a second upper contact on the peripheral circuit contact such that the second upper contact is electrically connected to the peripheral circuit contact.

7. The semiconductor device of claim 6, further comprising:
an upper insulating layer on an upper surface of the capacitor structure and an upper surface of the peripheral circuit insulating layer,
wherein the first upper contact and the second upper contact extend through the upper insulating layer in the vertical direction.

8. The semiconductor device of claim 2, wherein
the dam structure includes an inner wall and an outer wall,
the inner wall is in contact with the upper electrode, and
the outer wall is in contact with the peripheral circuit insulating layer.

9. The semiconductor device of claim 2, wherein
an upper surface of the capacitor structure is at a higher level than an upper surface of the dam structure, and
an upper surface of the peripheral circuit insulating layer is at a same level as the upper surface of the dam structure.

10. The semiconductor device of claim 2, wherein
the capacitor structure further includes a second cell supporter pattern on a second part of the sidewalls of the plurality of lower electrodes such that the second cell supporter pattern is at a vertical level higher than the first cell supporter pattern,
the peripheral circuit insulating layer further includes a second supporter layer on the second mold insulating layer, and
an upper surface of the second supporter layer is at a same vertical level as an upper surface of the second cell supporter pattern.

11. The semiconductor device of claim 1, wherein the peripheral circuit contact extends in the vertical direction through the first mold insulating layer, the first supporter layer, and the second mold insulating layer.

12. A semiconductor device comprising:
a substrate comprising a cell array area and a peripheral circuit area;
a capacitor structure on the cell array area of the substrate, the capacitor structure comprising
a plurality of lower electrodes extending in a vertical direction perpendicular to an upper surface of the substrate,
a first cell supporter pattern on a part of sidewalls of the plurality of lower electrodes,
a capacitor dielectric layer on the sidewalls of the plurality of lower electrodes and an upper surface and a bottom surface of the first cell supporter pattern, and
an upper electrode on the capacitor dielectric layer and covering the plurality of lower electrodes and the first cell supporter pattern;
a peripheral circuit insulating layer on the peripheral circuit area of the substrate, peripheral circuit insulating layer comprising
a first mold insulating layer,
a first supporter layer on the first mold insulating layer, the first supporter layer at a same vertical level as the first cell supporter pattern, and
a second mold insulating layer on the first supporter layer such that the first supporter layer is between the first and second mold insulating layers; and
a peripheral circuit contact on the peripheral circuit area of the substrate, peripheral circuit contact extending in the vertical direction through the peripheral circuit insulating layer.

13. The semiconductor device of claim 12, wherein
the capacitor structure further includes a second cell supporter pattern on a second part of the sidewalls of the plurality of lower electrodes such that the second cell supporter pattern is at a vertical level higher than the first cell supporter pattern,
the peripheral circuit insulating layer further includes a second supporter layer on the second mold insulating layer, and
an upper surface of the second supporter layer is at a same vertical level as an upper surface of the second cell supporter pattern.

14. The semiconductor device of claim 12, further comprising:
an upper insulating layer on an upper surface of the capacitor structure and an upper surface of the peripheral circuit insulating layer;
a first upper contact penetrating the upper insulating layer such that the first upper contact is electrically connected to the upper electrode; and
a second upper contact penetrating the upper insulating layer such that the second upper contact is electrically connected to the peripheral circuit contact.

15. The semiconductor device of claim 12, wherein the first supporter layer includes a same material as the first cell supporter pattern.

16. The semiconductor device of claim 12, wherein
the first cell supporter pattern includes a plurality of openings, and
the first supporter layer entirely covers an upper surface of the first mold insulating layer.

17. The semiconductor device of claim 12, further comprising:
a dam structure between the capacitor structure and the peripheral circuit insulating layer, the dam structure, in a planar view, surrounding the capacitor structure.

18. The semiconductor device of claim 17, wherein
the dam structure includes an upper surface at a same vertical level as an upper surface of the peripheral circuit insulating layer, and
an upper surface of the capacitor structure is disposed at a higher level than the upper surface of the dam structure.

19. The semiconductor device of claim 17, wherein
the dam structure includes an inner wall and an outer wall,
the inner wall of the dam structure is spaced apart from the first cell supporter pattern, and
the outer wall of the dam structure is in contact with a sidewall of the first supporter layer.

20. A semiconductor device comprising:
a substrate comprising a cell array area and a peripheral circuit area;
a capacitor structure formed on the cell array area of the substrate, the capacitor structure comprising
a plurality of lower electrodes extending in a vertical direction perpendicular to an upper surface of the substrate,
a first cell supporter pattern on a first portion of sidewalls of the plurality of lower electrodes,
a second cell supporter pattern on a second portion of the sidewalls of the plurality of lower electrodes such that the second cell supporter pattern is at a higher vertical level than the first cell supporter pattern,
a capacitor dielectric layer on the sidewalls of the plurality of lower electrodes, an upper surface and a bottom surface of the first cell supporter pattern, and an upper surface and a bottom surface of the second cell supporter pattern, and
an upper electrode on the capacitor dielectric layer and covering the plurality of lower electrodes, the first cell supporter pattern, and the second cell supporter pattern;
a peripheral circuit insulating layer on the peripheral circuit area of the substrate, the peripheral circuit insulating layer comprising:
a first mold insulating layer,
a first supporter layer on the first mold insulating layer, the first supporter layer at a same vertical level as the first cell supporter pattern,
a second mold insulating layer on the first supporter layer such that the first supporter layer is between the first and second mold insulating layers, and
a second supporter layer on the second mold insulating layer, the second supporter layer at a same vertical level as the second cell supporter pattern;
a dam structure between the capacitor structure and the peripheral circuit insulating layer, the dam structure, in a planar view, surrounding the capacitor structure;
a peripheral circuit contact on the peripheral circuit area of the substrate, and extending in the vertical direction through the peripheral circuit insulating layer;
an upper insulating layer on an upper surface of the capacitor structure and an upper surface of the peripheral circuit insulating layer;
a first upper contact penetrating the upper insulating layer such that the first upper contact is electrically connected to the upper electrode; and
a second upper contact penetrating the upper insulating layer such that the second upper contact is electrically connected to the peripheral circuit contact.
